(19) United States
(12) Patent Application Publication
(10) Pub. No.: US 2021/0057470 A1
(43) Pub. Date: Feb. 25, 2021

(54) SENSOR PACKAGE STRUCTURE

(71) Applicant: KINGPAK TECHNOLOGY INC., Hsin-Chu County (TW)

(72) Inventors: LI-CHUN HUNG, Hsin-Chu County (TW); CHIEN-CHEN LEE, Hsin-Chu County (TW); JUI-HUNG HSU, Hsin-Chu County (TW); SHENG YANG, Hsin-Chu County (TW); JO-WEI YANG, Hsin-Chu County (TW)

(21) Appl. No.: 16/803,430

(22) Filed: Feb. 27, 2020

(30) Foreign Application Priority Data
Aug. 22, 2019 (CN) 201910777935.3

(51) Int. Cl. H01L 27/146; H01L 23/31

(52) U.S. Cl. CPC H01L 27/14618; H01L 27/14636; H01L 23/3142

(57) ABSTRACT

A sensor package structure includes a substrate, a sensor chip disposed on the substrate, a light permeable layer arranged above the sensor chip, and a glue layer formed on the substrate. The light permeable layer includes a top surface, a bottom surface, and a plurality of lateral surfaces. The top surface has a plurality of edges respectively connected to the lateral surfaces covered by the glue layer. The glue layer includes a top curved surface having a top edge connected to the edges, and defines a plurality of tangent planes respectively passing through the edges and being tangent to the top curved surface. Between any one of the lateral surfaces and the adjacent one of the tangent planes, there exists an angle ranging from 38 to 53 degrees. And a difference between any two of the angles is equal to or less than 8 degrees.

### CROSS-REFERENCE TO RELATED PATENT APPLICATION

This application claims the benefit of priority to China Patent Application No. 201910777935.3, filed on Aug. 22, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure.

### BACKGROUND OF THE DISCLOSURE

In a conventional sensor package structure, a lateral side of a glass layer is covered by a package body, so that the glass layer can be fixed by the package body. Moreover, the conventional sensor package structure is only considered to make the volume size of the package, formed by covering the lateral side of the glass layer with the package body, not too small to firmly fix the glass layer in position. However, for the conventional sensor package structure, it is never considered the issue that as the volume size of the package is too large, the glass may easily crack due to thermal expansion and contraction during a temperature cycling test.

### SUMMARY OF THE DISCLOSURE

In response to the above-referenced technical inadequacies, the present disclosure provides a sensor package structure to effectively improve the issue associated with the conventional sensor package structure.

In one aspect, the present disclosure provides a sensor package structure, which includes a substrate, a sensor chip, a light permeable layer, and a glue layer. The substrate has a first board surface and a second board surface that is opposite to the first board surface. The sensor chip is disposed on the first board surface of the substrate and is electrically coupled to the substrate. An upper surface of the sensor chip has a sensing region. The light permeable layer is arranged above the sensor chip and includes a top surface, a bottom surface, and a plurality of lateral surfaces connected to the top surface and the bottom surface. The top surface has a plurality of edges respectively connected to the lateral surfaces, and the bottom surface of the light permeable layer faces toward the sensing region of the sensor chip. The glue layer is formed on the first board surface of the substrate and is configured to fix the light permeable layer. A peripheral portion of the sensor chip is embedded in the glue layer, the lateral surfaces of the light permeable layer are covered by the glue layer, and the top surface of the light permeable layer is exposed from the glue layer. The glue layer includes a curved top surface having an inner top edge connected to the edges of the top surface of the light permeable layer. The glue layer defines a plurality of tangent planes being tangent to the curved top surface and respectively passing through the edges, and between any one of the lateral surfaces and the adjacent one of the tangent planes, there exists an angle. A difference between any two of the angles in the glue layer is less than or equal to 8 degrees, and any one of the angles is within a range of 38-53 degrees.

Therefore, in the sensor package structure of the present disclosure, the angles between the curved top surface of the glue layer and the light permeable layer have been restricted for well controlling the glue volume outside of the lateral surfaces of the light permeable layer, so that not only the light permeable layer can be firmly fixed by the glue layer, but also the influence of thermal expansion and contraction of the glue layer can be effectively reduced. Accordingly, when the sensor package structure of the present disclosure is under a temperature cycling test, the light permeable layer will not be easily cracked due to thermal expansion and contraction of the glue layer.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a perspective view of a sensor package structure according to a first embodiment of the present disclosure.

FIG. 2 is a cross-sectional view taken along line II-II of FIG. 1.

FIG. 3 is a cross-sectional view taken along line III-III of FIG. 1.

FIG. 4 is a cross-sectional view of a sensor package structure according to a second embodiment of the present disclosure.

### DETAILED DESCRIPTION OF THE EXEMPLARY EMBODIMENTS

### First Embodiment

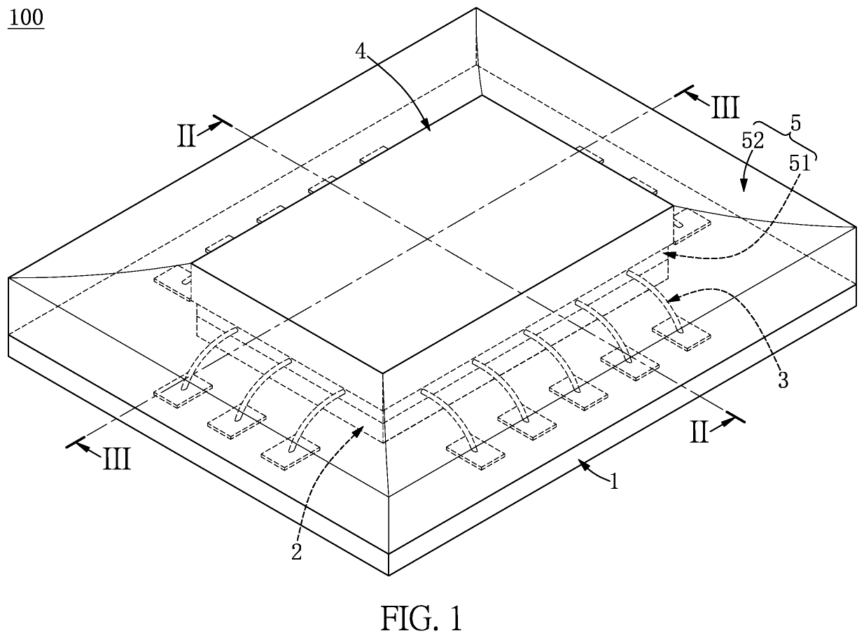

Referring to FIG. 1 to FIG. 3, a first embodiment of the present disclosure provides a sensor package structure 100. It should be noted that any package structure not encapsulating a sensor therein has a structural design different from that of the sensor package structure 100 of the present embodiment and is not suitable for a benchmark purpose.

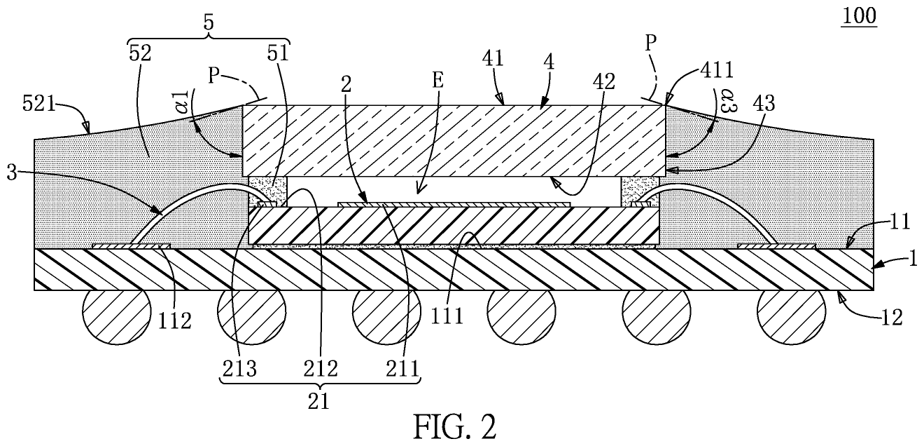

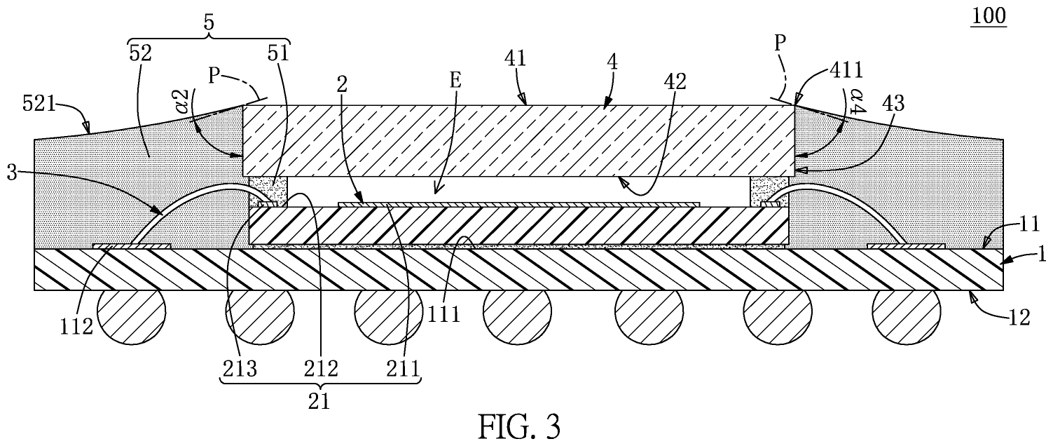

As shown in FIG. 2 and FIG. 3, the sensor package structure 100 includes a substrate 1, a sensor chip 2 disposed on the substrate 1, a plurality of metal wires 3 electrically coupled to the sensor chip 2 and the substrate 1, a light permeable layer 4 arranged above the sensor chip 2, and a glue layer 5 formed on the substrate 1 and fixing the light permeable layer 4. Herein, the sensor package structure 100 in the present embodiment, for example, has a light permeable layer 4 which won't be cracked after the sensor package structure 100 goes through a temperature cycling test according to condition B of the JEDEC standard, but the present disclosure is not limited thereto.

Moreover, the sensor package structure 100 in the present embodiment though includes the above components, but can be adjusted or changed according to design requirements. For example, in other embodiments not shown in the drawings of the present disclosure, the sensor package structure 100 can be provided without the metal wires 3, and the sensor chip 2 can be fixed onto the substrate 1 in a flip-chip manner.

It should be noted that FIG. 2 and FIG. 3 are cross-sectional views for the sake of easily describing the sensor package structure 100 of the present embodiment, and portions of the sensor package structure 100 not shown in FIG. 2 and FIG. 3 shall have corresponding structures. For example, FIG. 2 shows only two of the metal wires 3, but portions of the sensor package structure 100 not shown in FIG. 2 include other metal wires 3. The structure and connection relationship of each component of the sensor package structure 100 will be described in the following description.

The substrate 1 of the present embodiment is in a square-shape or a rectangular shape, but the present disclosure is not limited thereto. The substrate 1 has a first board surface 11 and a second board surface 12 opposite to the first board surface 11. The substrate 1 includes a chip-bonding region 111 arranged approximately on a center portion of the first board surface 11, and includes a plurality of first pads 112 arranged outside of the chip-bonding region 111 (or the sensor chip 2). The first pads 112 in the present embodiment are in an annular arrangement, but the present disclosure is not limited thereto. For example, in other embodiments not shown in the drawings of the present disclosure, the first pads 112 can be arranged in two rows respectively at two opposite sides of the chip-bonding region 111.

In addition, the substrate 1 can be further provided with a plurality of solder balls (not labeled) disposed on the second board surface 12. The substrate 1 can be soldered onto an electronic component (not shown) through the solder balls, thereby electrically connecting the sensor package structure 100 to the electronic component.

The sensor chip 2 in the present embodiment is an image sensing chip, but the present disclosure is not limited thereto. The sensor chip 2 is fixed onto the first board surface 11 of the substrate 1 (e.g., the chip-bonding region 111). In other words, the sensor chip 2 is arranged inboard of the first pads 112. Moreover, an upper surface 21 of the sensor chip 2 has a sensing region 211, n annular-shaped carrying region 212 surrounding the sensing region 211, and a plurality of second pads 213 arranged outside of the sensing region 211. In the present embodiment, the second pads 213 are disposed on the carrying region 212.

Specifically, the number and positions of the second solder pads 213 of the sensor chip 2 in the present embodiment correspond to those of the first solder pads 112 of the substrate 1. Each of the metal wires 3 has two opposite terminals, terminals at one end of the metal wires 3 are respectively connected to the first pads 112, and terminals at the other end of the metal wires 3 are respectively connected to the second pads 213, so that the substrate 1 and the sensor chip 2 can be electrically connected to each other through the metal wires 3.

The light-permeable layer 4 in the present embodiment is a transparent glass plate, but the present disclosure is not limited thereto. The light-permeable layer 4 is positioned by the glue layer 5 so as to be arranged above the sensor chip 2. The light-permeable layer 4 includes a top surface 41, a bottom surface 42, and a plurality of lateral surfaces 43 connected to the top surface 41 and the bottom surface 42. The top surface 41 has a plurality of edges 411 respectively connected to the lateral surfaces 43, and the bottom surface 42 of the light permeable layer 4 faces toward the sensing region 211 of the sensor chip 2.

Specifically, the top surface 41 of the light permeable layer 4 in the present embodiment is perpendicularly connected to each of the lateral surfaces 43, but the present disclosure is not limited thereto. For example, in other embodiments not shown in the drawings of the present disclosure, the top surface 41 of the light permeable layer 4 and each of the lateral surfaces 43 can have an obtuse angle or an acute angle there-between, or each of the lateral surfaces 43 can be in a step-like shape.

The glue layer 5 is formed on the first board surface 11 of the substrate 1. Specifically, a peripheral portion (such as the portion of the sensor chip 2 corresponding to the second pads 213) of the sensor chip 5 is embedded in the glue layer 5, the lateral surfaces 43 of the light permeable layer 4 are connected to (or covered by) the glue layer 5, and the top surface 41 of the light permeable layer 4 is exposed from the glue layer 5.

Moreover, the glue layer 5 includes a curved top surface 521 having an inner top edge connected to the edges 411 of the top surface 41 of the light permeable layer 4. The glue layer 5 defines a plurality of tangent planes P being tangent to the curved top surface 521 and respectively passing through the edges 411. Between each of the lateral surfaces 43 and the adjacent one of the tangent planes P are the angle α1-α4 within the glue layer 5. In the present embodiment, a difference between any two of the angles α1-α4 in the glue layer 5 is less than or equal to 8 degrees, and any one of the angles α1-α4 is within a range of 38-53 degrees. In addition, a difference between any adjacent two of the angles α1-α4 (e.g., the angles α1 and the angle α2) in the glue layer 5 is less than or equal to 3 degrees or is within a range of 1-5 degrees.

It should be noted that the glue layer 5 in the present disclosure can have a single piece structure or a combo structure. In the present embodiment, the glue layer 5 includes a supporting body 51 and a package body 52, and the package body 52 is a solidified liquid compound, but the present disclosure is not limited thereto.

The supporting body 51 is disposed on the carrying region 212 of the sensor chip 2, and is connected to the bottom surface 42 of the light permeable layer 4; that is to say, the supporting body 51 is sandwiched between the upper surface 21 of the sensor chip 2 and the bottom surface 42 of the light permeable layer 4. Moreover, the supporting layer 51 surrounds the sensing region 211, so that the upper surface 21 of the sensor chip 2, the bottom surface 42 of the light permeable layer 4, and the supporting layer 51 jointly define an enclosed space E. The sensing region 211 is arranged in the enclosed space E.

The package body 52 covers (or connects) the lateral surfaces 43 of the light permeable layer 4, and includes the curved top surface 521. The peripheral portion of the sensor chip 5 and the supporting body 51 both are embedded in the package body 52, a part of each of the metal wires 3 is embedded in the supporting body 51, and the other part of each of the metal wires 3 is embedded in the package body 52. Accordingly, the angles α1-α4 in the present embodiment are located in the package body 52. In other words, the tangent planes P are defined on the package body 52.

### Second Embodiment

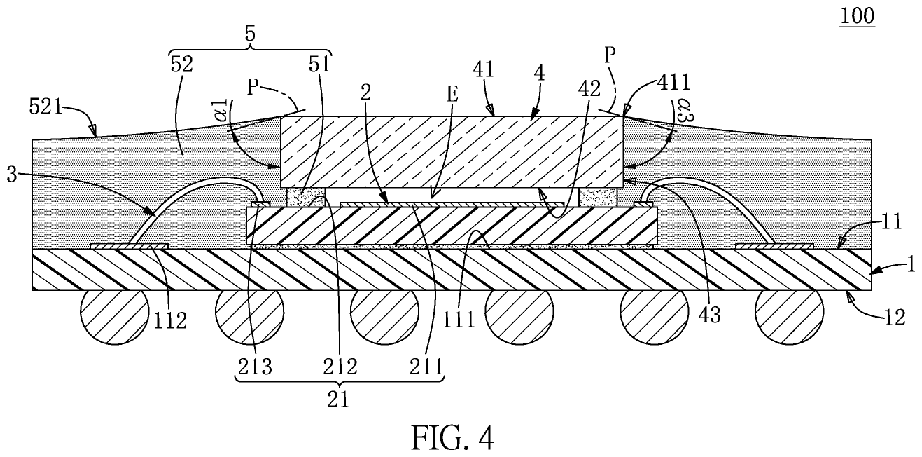

Referring to FIG. 4, a second embodiment of the present disclosure is similar to the first embodiment of the present disclosure, so that descriptions of the same components in the first and second embodiments of the present disclosure will be omitted for the sake of brevity, and the following description only discloses different features between the first and second embodiments. In the present embodiment, the second pads 213 are arranged outside of the supporting body 51, and each of the metal wires 3 is entirely embedded in the package body 52. According to the first and second embodiments, each of the metal wires 3 in the present disclosure can be at least partially embedded in the package body 52.

In conclusion, the sensor package structure of the present disclosure is formed based on the restriction of the angles between the curved top surface of the glue layer and the light permeable layer, for well controlling glue volume outside of the lateral surfaces of the light permeable layer, so that not only the light permeable layer can be firmly fixed by the glue layer, but also the influence from the thermal expansion and contraction of the glue layer can be effectively reduced. Accordingly, after the sensor package structure of the present disclosure underwent a temperature cycling test, the light permeable layer won't be cracked due to thermal expansion and contraction of the glue layer.

In addition, in order to prove that the disclosed sensor package structure could be less unaffected by thermal expansion and contraction of the glue layer, some experimental results in the following is illustrated. When the angles in the glue layer (e.g., the package body) are within a range of 40.8-42.1 degrees, no cracks can be found in the light permeable layer after the sensor package structure went through a temperature cycling test according to the B condition of the JEDEC standard. However, when the angles in the glue layer (e.g., the package body) are within a range of 53.2-53.9 degrees or 62.2-69.9 degrees, a portion of the light permeable layer adjacent to the lateral surfaces has at least one crack after the sensor package structure went through a temperature cycling test in terms of the JEDEC B-condition.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated.

Alternative embodiments will become apparent to those skilled in the art to which the present disclosure pertains without departing from its spirit and scope.

What is claimed is:

1. A sensor package structure, comprising:
a substrate having a first board surface and a second board surface that is opposite to the first board surface;
a sensor chip disposed on the first board surface of the substrate and electrically coupled to the substrate, wherein an upper surface of the sensor chip has a sensing region;
a light permeable layer arranged above the sensor chip and including a top surface, a bottom surface, and a plurality of lateral surfaces connected to the top surface and the bottom surface, wherein the top surface has a plurality of edges respectively connected to the lateral surfaces, and the bottom surface of the light permeable layer faces toward the sensing region of the sensor chip; and
a glue layer formed on the first board surface of the substrate and fixing the light permeable layer, wherein a peripheral portion of the sensor chip is embedded in the glue layer, the lateral surfaces of the light permeable layer are covered by the glue layer, and the top surface of the light permeable layer is exposed from the glue layer,
wherein the glue layer includes a curved top surface having an inner top edge connected to the edges of the top surface of the light permeable layer, the glue layer defines a plurality of tangent planes being tangent to the curved top surface and respectively passing through the edges, and between any one of the lateral surfaces and the adjacent one of the tangent planes, there exists an angle, and a difference between any two of the angles in the glue layer is less than or equal to 8 degrees, and any one of the angles is within a range of 38-53 degrees.

2. The sensor package structure according to claim 1, wherein a difference between any adjacent two of the angles in the glue layer is less than or equal to 3 degrees.

3. The sensor package structure according to claim 1, wherein a difference between any adjacent two of the angles in the glue layer is within a range of 1-5 degrees.

4. The sensor package structure according to claim 1, wherein the glue layer includes:
a supporting body sandwiched between the upper surface of the sensor chip and the bottom surface of the light permeable layer, wherein the supporting body surrounds the sensing region, so that the upper surface of the sensor chip, the bottom surface of the light permeable layer, and the supporting layer jointly define an enclosed space, and wherein the sensing region is arranged in the enclosed space; and
a package body covering the lateral surfaces of the light permeable layer and including the curved top surface, wherein the sensor chip and the supporting body are embedded in the package body.

5. The sensor package structure according to claim 4, wherein the substrate includes a plurality of first pads disposed on the first board surface, and the sensor chip includes a plurality of second pads disposed on the upper surface and arranged around the sensing region, and wherein the sensor package structure includes a plurality of metal wires, terminals at one end of the metal wires are connected to the first pads, terminals at another end of the metal wires are connected to the second pads, and each of the metal wires is at least partially embedded in the package body.

6. The sensor package structure according to claim 5, wherein the second pads are embedded in the supporting body, and a part of each of the metal wires is embedded in the supporting body.

7. The sensor package structure according to claim 5, wherein the second pads are arranged outside of the supporting body, and each of the metal wires is entirely embedded in the package body.

8. The sensor package structure according to claim 4, wherein the package body is a solidified liquid compound.

9. The sensor package structure according to claim 1, wherein no cracks are formed on the light permeable layer after the sensor package structure goes through a thermal cycling test according to condition B of the Joint Electron Device Engineering Council (JEDEC) standard.

10. The sensor package structure according to claim 1, wherein the top surface of the light permeable layer is perpendicularly connected to each of the lateral surfaces.
